(19) United States
(12) Patent Application Publication
(10) Pub. No.: US 2024/0170389 A1
(43) Pub. Date: May 23, 2024

(54) THREE-DIMENSIONAL MEMORY DEVICES AND SYSTEM HAVING THE SAME

(71) Applicant: YANGTZE MEMORY TECHNOLOGIES CO., LTD., Wuhan (CN)

(72) Inventors: Jiajia Wu, Wuhan (CN); Bin Yuan, Wuhan (CN); Zongke Xu, Wuhan (CN); Zhen Guo, Wuhan (CN); Beibei Li, Wuhan (CN); Xiangning Wang, Wuhan (CN); Zhu Yang, Wuhan (CN); Qiangwei Zhang, Wuhan (CN); Zongliang Huo, Wuhan (CN)

(21) Appl. No.: 17/991,050

(22) Filed: Nov. 21, 2022

(51) Int. Cl. H01L 23/522; H01L 27/11556; H01L 27/11582

(52) U.S. Cl. CPC H01L 23/5221; H01L 27/11556; H01L 27/11582

(57) ABSTRACT

In certain aspects, a three-dimensional (3D) memory device includes a stack structure including alternating conductive layers and dielectric layers and having at least two core regions and a staircase region between the two core regions, and bridge structures connecting the two core regions and extending through the staircase region in a first direction. A first bridge structure of the bridge structures includes at least two current paths between the two core regions.

### BACKGROUND

The present disclosure relates to memory devices, and systems having the same.

Planar memory cells are scaled to smaller sized by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation of planar memory cells. The 3D memory architecture includes a memory array and peripheral circuits for facilitating operations of the memory array.

### SUMMARY

In one aspect, a three-dimensional (3D) memory device includes: a stack structure comprising alternating conductive layers and dielectric layers and having at least two core regions and a staircase region between the two core regions, and bridge structures connecting the two core regions and extending through the staircase region in a first direction. A first bridge structure of the bridge structures comprises at least two current paths between the two core regions.

In some implementations, the 3D memory device further includes: an isolation structure extending through the staircase region in the first direction, a first slit structure discontinuously extending through the staircase region in the first direction, and a second slit structure discontinuously extending through the staircase region in the first direction. A first current path of the at least two current paths is between the isolation structure and the first slit structure, and a second current path of the at least two current paths is between the first slit structure and the second slit structure.

In some implementations, the isolation structure separates two bridge structures in two respective memory blocks.

In some implementations, the first current path and the second current path are interconnected through discontinuous portions of the first slit structure.

In some implementations, the 3D memory device further includes: first dummy channel structures extending into the stack structure and being arranged side-by-side in the first direction and in contact with the first slit structure at a close side toward the isolation structure, second dummy channel structures extending into the stack structure and being arranged side-by-side in the first direction and in contact with the first slit structure at a remote side toward the isolation structure, and third dummy channel structures extending into the stack structure and being arranged side-by-side in the first direction and in contact with the second slit structure at a close side toward the isolation structure. The first current path of the at least two current paths is between the isolation structure and the first dummy channel structures, and the second current path of the at least two current paths is between the second dummy channel structures and the third dummy channel structures.

In some implementations, a width of the first bridge structure in a remote side toward the substrate is ranged from the isolation structure to that of the third dummy channel structures, and the width of the first bridge structure is no less than 1.25 μm.

In some implementations, the 3D memory device further includes channel structures each extending in the stack structure in the core regions.

In some implementations, the first bridge structure connects two of the conductive layers in two respective core regions.

In some implementations, a material of the bridge structures comprises tungsten (W), cobalt (Co), copper (Cu), aluminum (Al), polycrystalline silicon (polysilicon), doped silicon, silicides, or any combination thereof.

In another aspect, a three-dimensional (3D) memory device includes: a stack structure including alternating conductive layers and dielectric layers and having at least two core regions and a staircase region between the two core regions, bridge structures connecting the two core regions and extending through the staircase region in a first direction, an isolation structure extending through the staircase region in the first direction, a first slit structure discontinuously extending through the staircase region in the first direction, a second slit structure discontinuously extending through the staircase region in the first direction, and at least three dummy channel structures extending into the stack structure and being arranged side-by-side in the first direction and in contact with the first slit structure at a close side toward the isolation structure, wherein a width of the bridge structure is ranged from the isolation structure to the third dummy channel structures.

In some implementations, the at least three dummy channel structures include: first dummy channel structures extending into the stack structure and being arranged side-by-side in the first direction and in contact with the first slit structure at a close side toward the isolation structure, second dummy channel structures extending into the stack structure and being arranged side-by-side in the first direction and in contact with the first slit structure at a remote side toward the isolation structure, and third dummy channel structures extending into the stack structure and being arranged side-by-side in the first direction and in contact with the second slit structure at a close side toward the isolation structure.

In some implementations, the isolation structure separates two bridge structures in two respective memory blocks.

In some implementations, a width of the first bridge structure in a remote side toward the substrate is ranged from the isolation structure to that of the third dummy channel structures, and the width of the first bridge structure is no less than 1.25 μm.

In some implementations, the 3D memory device further includes channel structures each extending in the stack structure in the core regions.

In some implementations, the bridge structure connects two of the channel structures in two respective core regions.

In some implementations, a material of the bridge structure comprises tungsten (W), cobalt (Co), copper (Cu), aluminum (Al), polycrystalline silicon (polysilicon), doped silicon, silicides, or any combination thereof.

In still another aspect, a system includes: a three-dimensional (3D) memory device configured to store data and a memory controller coupled to the 3D memory device and configured to control the 3D memory device. The 3D memory device includes: a stack structure including alternating conductive layers and dielectric layers and having at least two core regions and a staircase region between the two core regions, and bridge structures connecting the two core regions and extending through the staircase region in a first direction. A first bridge structure of the bridge structures includes at least two current paths between the two core regions.

In some implementations, the 3D memory device further includes: an isolation structure extending through the staircase region in the first direction, a first slit structure discontinuously extending through the staircase region in the first direction, and a second slit structure discontinuously extending through the staircase region in the first direction. A first current path of the at least two current paths is between the isolation structure and the first slit structure, and a second current path of the at least two current paths is between the first slit structure and the second slit structure.

In some implementations, the first current path and the second current path are interconnected through discontinuous portions of the first slit structure.

In some implementations, the 3D memory device further includes: first dummy channel structures extending into the stack structure and being arranged side-by-side in the first direction and in contact with the first slit structure at a close side toward the isolation structure, second dummy channel structures extending into the stack structure and being arranged side-by-side in the first direction and in contact with the first slit structure at a remote side toward the isolation structure, and third dummy channel structures extending into the stack structure and being arranged side-by-side in the first direction and in contact with the second slit structure at a close side toward the isolation structure. The first current path of the at least two current paths is between the isolation structure and the first dummy channel structures, and the second current path of the at least two current paths is between the second dummy channel structures and the third dummy channel structures.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic circuit diagram of a memory device including peripheral circuits, according to some implementations of the present disclosure.

FIG. 2 illustrates a block diagram of a memory device including a memory cell array and peripheral circuits, according to some implementations of the present disclosure.

FIG. 3 illustrates a top perspective view of a 3D memory device, according to some implementations of the present disclosure.

FIG. 4A illustrates an enlarged view of part of the staircase region of the memory cell array of a 3D memory device, according to some implementations of the present disclosure.

FIG. 4B illustrates an enlarged view of part of the staircase region of the memory cell array of another 3D memory device, according to some implementations of the present disclosure.

FIG. 5A illustrates an enlarged view of part of the staircase region of the memory cell array of a 3D memory device, according to some implementations of the present disclosure.

FIG. 5B illustrates an enlarged view of part of the staircase region of the memory cell array of another 3D memory device, according to some implementations of the present disclosure.

FIGS. 6A-6B illustrate perspective views of part of the staircase region of the memory cell array of a 3D memory device, according to some implementations of the present disclosure.

FIGS. 6C-6D illustrate perspective views of part of the staircase region of the memory cell array of another 3D memory device, according to some implementations of the present disclosure.

FIG. 7 illustrates a block diagram of an exemplary system having a 3D memory device, according to some implementations of the present disclosure.

FIG. 8A illustrates a diagram of an exemplary memory card having a 3D memory device, according to some implementations of the present disclosure.

FIG. 8B illustrates a diagram of an exemplary solid-state drive (SSD) having a 3D memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (e.g., single crystalline silicon, c-Si), silicon germanium (SiGe), gallium arsenide (GaAs), germanium (Ge), silicon on insulator (SOI), or any other suitable materials. Alternatively, the substrate can be made from an electrically non-conductive material, such as a glass, a plastic, or a sapphire wafer.

As used herein, the term “x-,” “y-,” and “z-,” axes are used herein to illustrate the spatial relationships of the components in the 3D memory device according to some implementation of the present disclosure. Substrate may include two lateral surfaces extending laterally in the x-y plane: a front surface on the front side of the wafer, and a back surface on the backside opposite to the front side of the wafer. The x- and y-directions are two orthogonal directions in the wafer plane: x-direction is the word line extending direction, and the y-direction is the bit line extending direction. The z-axis is perpendicular to both the x- and y-axes.

As used herein, whether one component (e.g., a layer or a device) is “on,” “above,” or “below” another component (e.g., a layer or a device) of a semiconductor device (e.g., 3D memory device) is determined relative to the substrate of the semiconductor device (e.g., substrate) in the z-direction (the vertical direction perpendicular to the x-y plane) when the substrate is positioned in the lowest plane of the semiconductor device in the z-direction. The same notion for describing spatial relationships is applied throughout the present disclosure.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or +30% of the value).

As used herein, the term “3D memory device” refers to a semiconductor device with memory cell transistors on a laterally-oriented substrate so that the memory cells extend in the vertical direction with respect to the substrate. As used herein, the term “vertical/vertically” means nominally perpendicular to the lateral surface of a substrate.

As used herein, the term “memory string” refers to one or more rows of memory cells (or channel structures) between an SSG cut structure and a slit structure, the SSG cut structure being a bottom-select-gate (BSG) cut structure. As used herein, the term “memory finger” refers to one or more rows of memory cells (or channel structures) between adjacent slit structures. As used herein, a “string” refers to the physical location/area where a memory string is located. Memory cells in a memory string may be located in a corresponding string of the 3D memory device. As used herein, a “finger” refers to the physical location/area where a memory finger is located. Memory cells in a memory finger may be located in a corresponding finger of the 3D memory device. As used herein, the term “dielectric string” refers to one or more rows of channel structures before a gate-replacement process to form a plurality of conductive layers (e.g., word lines).

In some 3D memory devices, memory cells for storing data are vertically stacked through a stacked storage structure (e.g., a memory stack). To control memory cells in various portions of a 3D memory device, SSG cut structures, such as BSG cut structures, are formed in the 3D memory device to divide the memory cells in a memory block into memory fingers and memory strings. Word line contacts are formed to be in contact with different portions of the memory cells such that a voltage can be applied to a respective portion of memory cells. By applying voltages on respective portions of the memory cells, memory blocks, memory fingers, and memory strings can be separately controlled to implement block control, finger control, and string control. Different memory blocks, memory fingers, and memory strings can be controlled to perform operations such as write, erase, read, etc.

With the development of three-dimensional (3D) memory devices, such as 3D NAND Flash memory devices, the more memory structures being stacked, the higher the possibility conductive layers that interconnected between being failed to be electrically connected. That is, during the filling process, the higher depth and higher aspect ratio of the trenches to fill to form these conductive layers, the higher possibility these trenches are not being filled properly. As such, voids are generated during the filing process, which cause a short circuit, thereby reducing the reliability of the memory device. Furthermore, due to the higher depth and higher aspect ratio of the trenches, the thicker the photoresist layer for photolithography process will be needed. These extremely thick photoresist layers may easily collapse at the edges of each die. For example, for 64, 96, 128, 160, 192, 224, 256, or more stacks of memory devices, these issues may get much worse. Therefore, both the forming of conductive layers and the forming of the photoresist layer may require a wider processing window to form properly and to increase the reliability for highly stacked memory devices.

To address one or more of the aforementioned issues, the present disclosure introduces a solution in which the width of the conductive layers (e.g., bridge structures) that extend across the staircase region and are connected between two core regions of the memory device are expanded slightly to allow at least two current paths to flow through. By allowing at least two current paths to flow through, it significantly reduces the short circuit issue due to the missing filing trench or voids that blocks the current path. That is, even if one current path is blocked due to the voids or missing filling of the trench, the other or more current paths may still be available for electrically connection, thereby increasing the reliability of the memory device. Also, by expanding the width of the bridge structure slightly and properly, it broadens the processing window to form these thick photoresist layers and filling the deep trenches (e.g., with conductive materials for bridge structures). In particular, this is especially helpful in the processing of highly stacked memory devices (e.g., 64, 96, 128, 160, 192, 224, 256, or more stacks).

It is noted that more width of the bridges structure means more the area size of the memory device are consumed. As such, the width of the bridge structures should not be expanded for more than addressing the above-mentioned issues, and the number of current paths may also depend on the size of each memory block of the memory device.

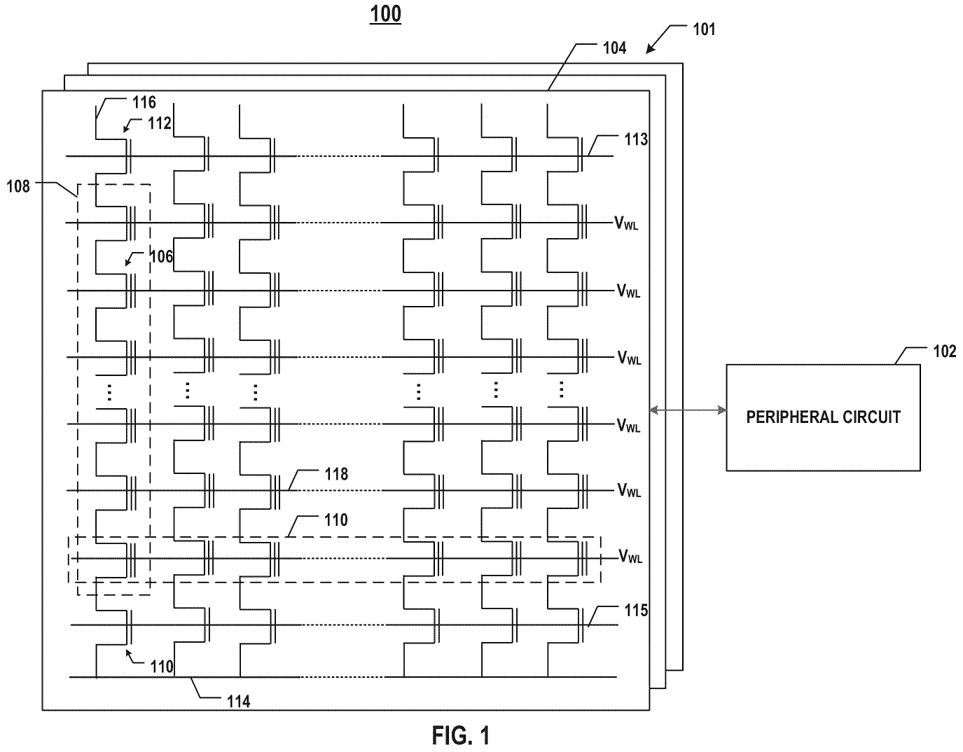

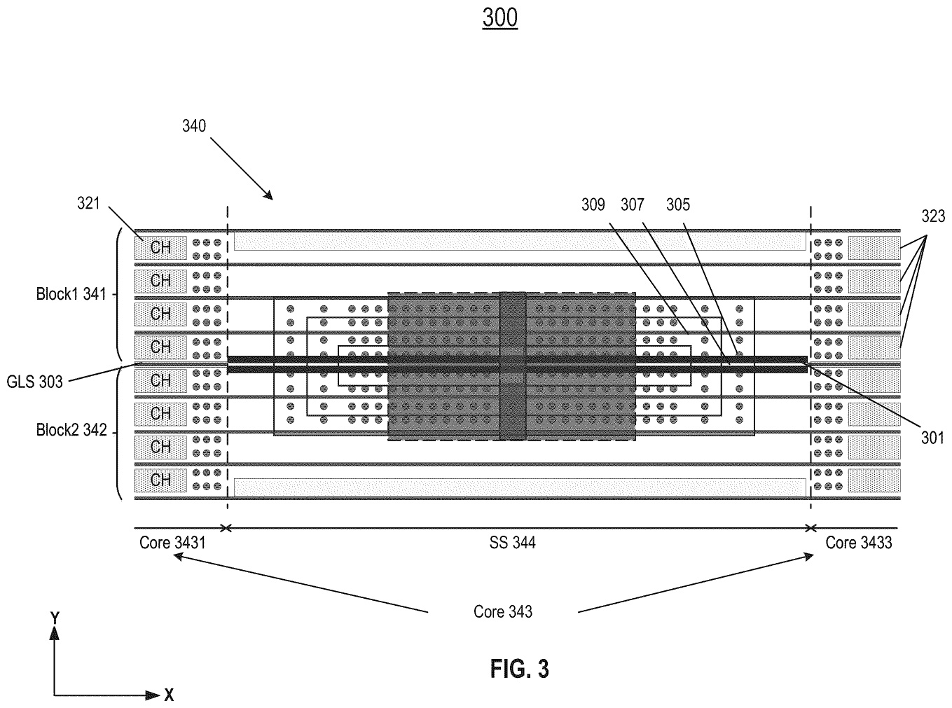

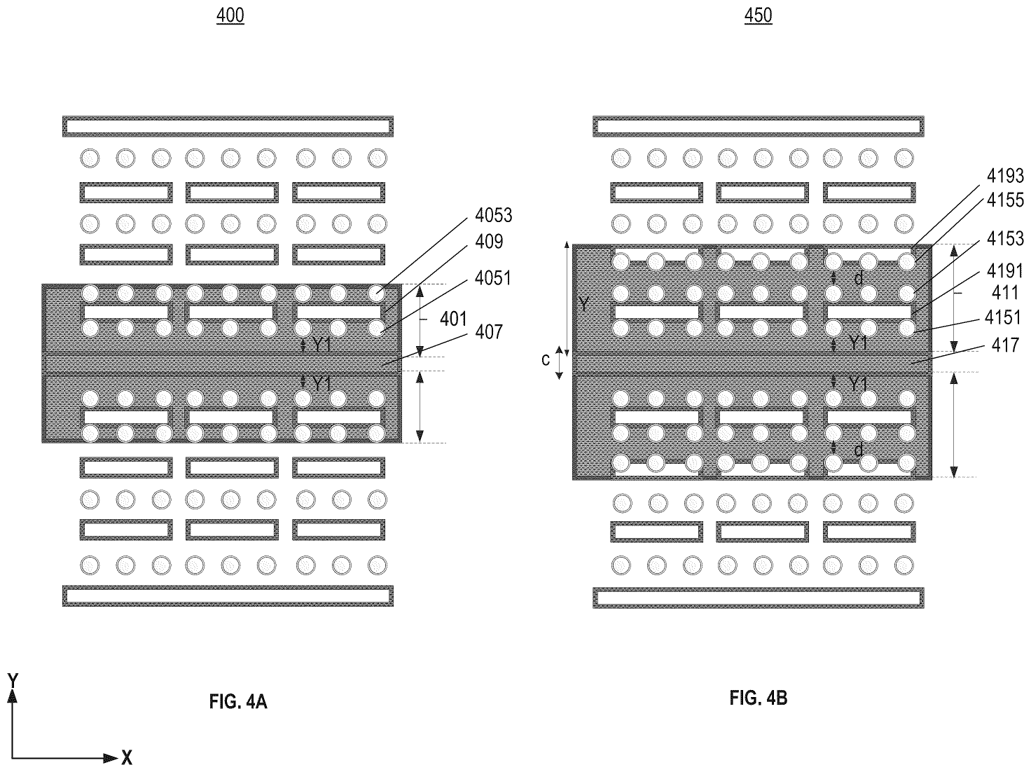

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of 3D NAND memory strings 108 each extending vertically above a substrate (not shown). In some implementations, each 3D NAND memory string 108 includes a plurality of memory cells 106 coupled in series and stacked vertically. Each memory cell 106 can hold a continuous, analog value, such as an electrical voltage or charge, which depends on the number of electrons trapped within a region of memory cell 106. Each memory cell 106 can be either a floating gate type of memory cell including a floating-gate transistor or a charge trap type of memory cell including a charge-trap transistor. Each array of 3D NAND memory strings 108 can include one or more 3D memory devices. For example, FIG. 3 illustrates an exemplary 3D memory device 300, and FIGS. 4A and 4B illustrate some exemplary 3D memory devices 400 and 450.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in four or more memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1, each 3D NAND memory string 108 can include a source select gate (SSG) transistor 110 at its source end and a drain select gate (DSG) transistor 112 at its drain end. SSG transistor 110 and DSG transistor 112 can be configured to activate selected 3D NAND memory strings 108 (columns of the array) during read and program operations. In some implementations, the sources of SSG transistors 110 of 3D NAND memory strings 108 in the same block 104 are coupled through a same source line (SL) 114, e.g., a common SL, for example, to the ground. DSG transistor 112 of each 3D NAND memory string 108 is coupled to a respective bit line 116 from which data can be read or programmed via an output bus (not shown), according to some implementations. In some implementations, each 3D NAND memory string 108 is configured to be selected or unselected by applying a select signal (e.g., a select voltage above the threshold voltage of DSG transistor 112) or a deselect signal (e.g., a deselect voltage such as 0 V) to respective DSG transistor 112 through one or more DSG lines 113 and/or by applying a select voltage (e.g., above the threshold voltage of SSG transistor 110) or a deselect voltage (e.g., 0 V) to respective SSG transistor 110 through one or more SSG lines 115.

As shown in FIG. 1, 3D NAND memory strings 108 can be organized into multiple blocks 104, each of which can have a common source line 114. In some implementations, each block 104 is the basic data unit for erase operations, i.e., all memory cells 106 on the same block 104 are erased at the same time. Memory cells 106 can be coupled through word lines 118 that select which row of memory cells 106 is affected by read and program operations. In some implementations, each word line 118 is coupled to a row of memory cells 106, which is the basic data unit for program and read operations. Each word line 118 can be coupled to a plurality of control gates (gate electrodes) at each memory cell 106 in respective row and a gate line coupling the control gates.

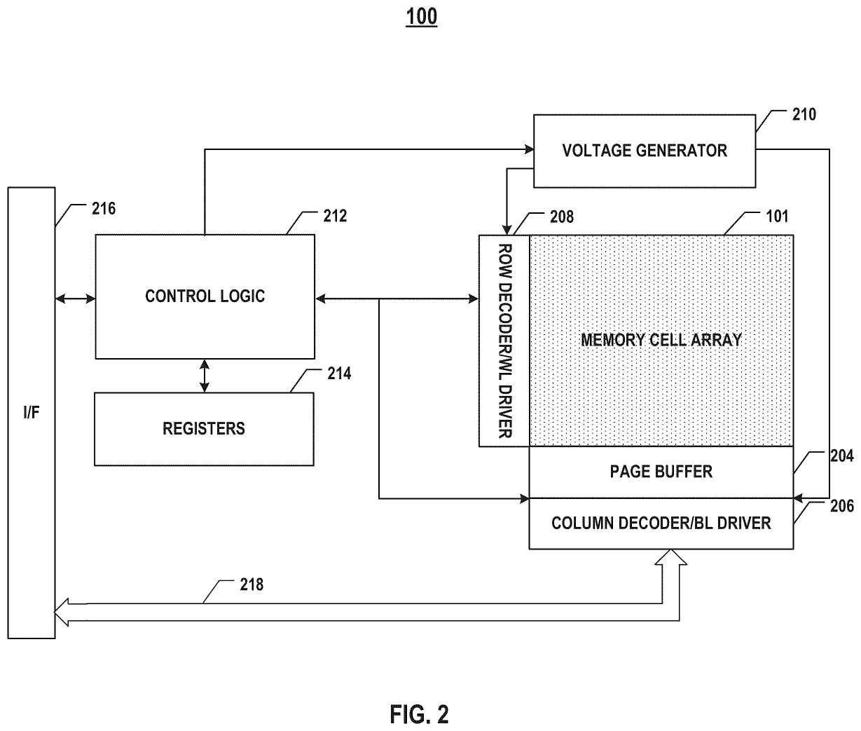

Peripheral circuits 102 can be coupled to memory cell array 101 through bit lines 116, word lines 118, source lines 114, SSG lines 115, and DSG lines 113. As described above, peripheral circuits 102 can include any suitable circuits for facilitating the operations of memory cell array 101 by applying and sensing voltage signals and/or current signals through bit lines 116 to and from each target memory cell 106 through word lines 118, source lines 114, SSG lines 115, and DSG lines 113. Peripheral circuits 102 can include various types of peripheral circuits formed using complementary metal-oxide semiconductor (CMOS) technologies. For example, FIG. 2 illustrates some exemplary peripheral circuits 102 including a page buffer 204, a column decoder/bit line driver 206, a row decoder/word line driver 208, a voltage generator 210, control logic 212, registers 214, an interface (I/F) 216, and a data bus 218. It is understood that in some examples, additional peripheral circuits 102 may be included as well.

Page buffer 204 can be configured to buffer data read from or programmed to memory cell array 101 according to the control signals of control logic 212. In one example, page buffer 204 may store one page of program data (write data) to be programmed into one row of memory cell array 101. In another example, page buffer 204 also performs program verify operations to ensure that the data has been properly programmed into memory cells 106 coupled to selected word lines 118.

Row decoder/word line driver 208 can be configured to be controlled by control logic 212 and select or unselect a block 104 of memory cell array 101 and select or unselect a word line 118 of selected block 104. Row decoder/word line driver 208 can be further configured to drive memory cell array 101. For example, row decoder/word line driver 208 may drive memory cells 106 coupled to the selected word line 118 using a word line voltage generated from voltage generator 210. In some implementations, row decoder/word line driver 208 can include a decoder and string drivers (driving transistors) coupled to local word lines and word lines 118.

Voltage generator 210 can be configured to be controlled by control logic 212 and generate the word line voltages (e.g., read voltage, program voltage, pass voltage, local voltage, and verification voltage) to be supplied to memory cell array 101. In some implementations, voltage generator 210 is part of a voltage source that provides voltages at various levels of different peripheral circuits 102 as described below in detail. Consistent with the scope of the present disclosure, in some implementations, the voltages provided by voltage generator 210, for example, to row decoder/word line driver 208 and page buffer 204 are above certain levels that are sufficient to perform the memory operations. For example, the voltages provided to page buffer 204 may be between 2 V and 3.3 V, such as 3.3 V, and the voltages provided to row decoder/word line driver 208 may be greater than 3.3 V, such as between 3.3 V and 30 V.

Column decoder/bit line driver 206 can be configured to be controlled by control logic 212 and select one or more 3D NAND memory strings 108 by applying bit line voltages generated from voltage generator 210. For example, column decoder/bit line driver 206 may apply column signals for selecting a set of N bits of data from page buffer 204 to be outputted in a read operation.

Control logic 212 can be coupled to each peripheral circuit 102 and configured to control operations of peripheral circuits 102. Registers 214 can be coupled to control logic 212 and include status registers, command registers, and address registers for storing status information, command operation codes (OP codes), and command addresses for controlling the operations of each peripheral circuit 102.

Interface 216 can be coupled to control logic 212 and configured to interface memory cell array 101 with a memory controller (not shown). In some implementations, interface 216 acts as a control buffer to buffer and relay control commands received from the memory controller and/or a host (not shown) to control logic 212 and status information received from control logic 212 to the memory controller and/or the host. Interface 216 can also be coupled to page buffer 204 and column decoder/bit line driver 206 via data bus 218 and act as an input/output (I/O) interface and a data buffer to buffer and relay the program data received from the memory controller and/or the host to page buffer 204 and the read data from page buffer 204 to the memory controller and/or the host. In some implementations, interface 216 and data bus 218 are part of an I/O circuit of peripheral circuits 102.

FIG. 3 illustrates a top perspective view of a memory cell array (e.g., corresponding to memory cell array 101 in FIG. 1) of an exemplary 3D memory device 300, according to some implementations of the present disclosure. The memory cell array of 3D memory device 300 may include one or more memory blocks (e.g., first memory block 341, second memory block 342). Each memory block may include one or more memory fingers 323 extending in a first direction (e.g., x-direction or a first lateral direction) separated by one or more slit structures 303. Each memory block may include one or more core regions 343 and one or more staircase regions 344. Each memory finger 323 in each core region 343 may include one or more memory strings (e.g., corresponding to 3D NAND memory strings 108 in FIG. 1) extending in a second direction (e.g., a z-direction or a vertical direction) perpendicular to the first direction. One or more channel structures 321 may be formed in each memory block. The intersection of the channel structures and the word lines (or conductive layers) may form one or more memory cells in the memory blocks/fingers/strings.

In some implementations, channel structures 321 formed in core regions 343 may include a channel hole filled with a semiconductor layer (e.g., as a semiconductor channel) and a composite dielectric layer (e.g., as a memory film). In some implementations, the semiconductor channel includes silicon, such as amorphous silicon, polysilicon, or single crystalline silicon. In some implementations, the memory film is a composite layer including a tunneling layer, a storage layer (also known as a “charge trap layer”), and a blocking layer. The remaining space of channel structure 321 can be partially or fully filled with a capping layer including dielectric materials, such as silicon oxide, and/or an air gap. Channel structure 321 can have a cylinder shape (e.g., a pillar shape). The capping layer, the semiconductor channel, the tunneling layer, the storage layer, and the blocking layer of the memory film are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high-k dielectrics, or any combination thereof. In one example, the memory film can include a composite layer of silicon oxide/silicon oxynitride/silicon oxide (ONO).

In some embodiments, channel structure 321 further includes a channel plug (not shown) in the top portion (e.g., at the upper end) of channel structure 321. As used herein, the “upper end” of a component (e.g., channel structure 321) is the end farther away from a substrate in the z-direction, and the “lower end” of the component (e.g., channel structure 321) is the end closer to the substrate in the z-direction when the substrate is positioned in the lowest plane of 3D memory device 300. The channel plug can include semiconductor materials (e.g., polysilicon). In some embodiments, the channel plug functions as the drain of the NAND memory string.

The memory strings in a first core region 3431 and a second core region 3433 are conductively connected through bridge structure 301. Through bridge structure 301 and isolation structure 307 in staircase region 344, it allows the conductive connection to be formed between the memory strings in two respective core regions. In some implementations, isolation structure 307, as well as bridge structure 301, defines the electric current that can flow in the paths. Isolation structure 307, as well as bridge structure 301, also extends in the first direction (e.g., the x-direction or the first lateral direction) to divide staircase regions 344 into a plurality of divisions (e.g., different memory fingers or different memory blocks).

Bridge structure 301 can include vertically interleaved conductive layers and dielectric layers (not shown), and the conductive layers (e.g., metal layers or polysilicon layers) can function as part of word lines. In some implementations, bridge structure 301 may be only the conductive layers. The conductive layers of bridge structure 301 can include conductive materials including, but not limited to, tungsten (W), cobalt (Co), copper (Cu), aluminum (Al), polycrystalline silicon (polysilicon), doped silicon, silicides, or any combination thereof. The dielectric layers of bridge structure 301 can include dielectric materials including, but not limited to, silicon oxide, silicon nitride, silicon oxynitride, or any combination thereof. In some implementations, the conductive layers include metals, such as tungsten, and the dielectric layers include silicon oxide.

In some implementations, isolation structure 307 may be suitable dielectric materials including, but not limited to, silicon oxide, silicon nitride, silicon oxynitride, or any combination thereof.

One or more slit structures 309 may or may not extend continuously in the x-direction in staircase regions 344. In some implementations, as shown in FIG. 4A, first slit structures 409 (corresponding to slit structure 309 in FIG. 3) may not extend continuously in the x-direction and may each be disconnected in the x-direction. In some implementations, bridge structure 401 (corresponding to bridge structure 301) may extend between the adjacent disconnected portions of first slit structures 409 in a third direction (e.g., a y-direction or a second lateral direction) perpendicular to the first and second direction.

In some implementations, slit structures 309 may be suitable dielectric materials including, but not limited to, silicon oxide, silicon nitride, silicon oxynitride, or any combination thereof.

One or more dummy channel structures 305 may extend in the z-direction in staircase region 344 and core regions 343. In some implementations, dummy channel structures 305 may be arranged side-by-side in the x-direction and in contact with discontinuous slit structures 309. Since dummy channel structures 305, slit structures 309, and isolation structure 307 are, for example, dielectric materials, or at least not as conductive as bridge structure 301, the electric current paths within bridge structure 301 are defined by dummy channel structures 305, slit structures 309, and isolation structure 307. In some implementations, dummy channel structures 305 may have a cylinder shape (e.g., a pillar shape). It can also be other shape including a cone shape, a pyramid shape, a triangular prism shape, a cuboid shape, a hexagonal prism shape, or a trapezoidal prism shape.

In some implementations, dummy channel structures 305 may be suitable dielectric materials including, but not limited to, silicon oxide, silicon nitride, silicon oxynitride, or any combination thereof.

As shown in FIG. 3. staircase region 344 may be in the center of stack structure 340, and core region 343 may be at two sides of staircase region 344 of stack structure 340 in the x-direction (e.g., the word line direction), according to some implementations. In another implementation, the core region may be in the center of the stack structure, while the staircase region may be at two sides of the core region of the stack structure in the x-direction (e.g., the word line direction). In some implementations, 3D memory device 300 may include multiple core regions 343 and staircase regions 344 which are connected by multiple bridge structures 301. In some implementations, bridge structure 301 may include a stair shape or pattern shape extending in the z-direction (e.g., vertical direction) that can reduce the stress of the chip. In some implementations, bridge structure 301 is configured to connect the conductive layers of memory strings laterally (e.g., in the y- or x-direction) among different blocks or among different array common source (ACS) in the same block. In some implementations, bridge structure 301 may include two extended portions (not shown) each extending in the z-direction to contact two conductive layers which are connected to two respective ACSs. As such, bridge structure 301 may be an upside-down U-shape in a cross-sectional view (e.g., in the x- or y-direction).

In some implementations, the staircase region can be formed by performing a plurality of so-called “trim-etch” cycles to the dielectric layer pairs of dielectric stack toward the substrate. Next, a channel hole (not shown) is formed extending vertically through the dielectric stack, and a memory film (not shown) and a semiconductor channel (not shown) are sequentially formed along a sidewall of the channel hole.

FIG. 4A shows an enlarged view of part of the staircase region of the memory cell array of 3D memory device 400 according to some implementations of the present disclosure. For the simplicity of description, parts of 3D memory device 400 labeled with the same numerals are the same as or similar to those in 3D memory device 300, and the detailed descriptions are not repeated herein.

As shown in FIG. 4A, bridge structure 401 and isolation structure 407 are arranged along the x-direction in the staircase region. The width (e.g., the distance along the y-direction) of bridge structure 401 may be ranged from isolation structure 407 to a second dummy channel structure 4053 adjacent to a first slit structure 409 and at a remote side of first slit structure 409 toward isolation structure 407.

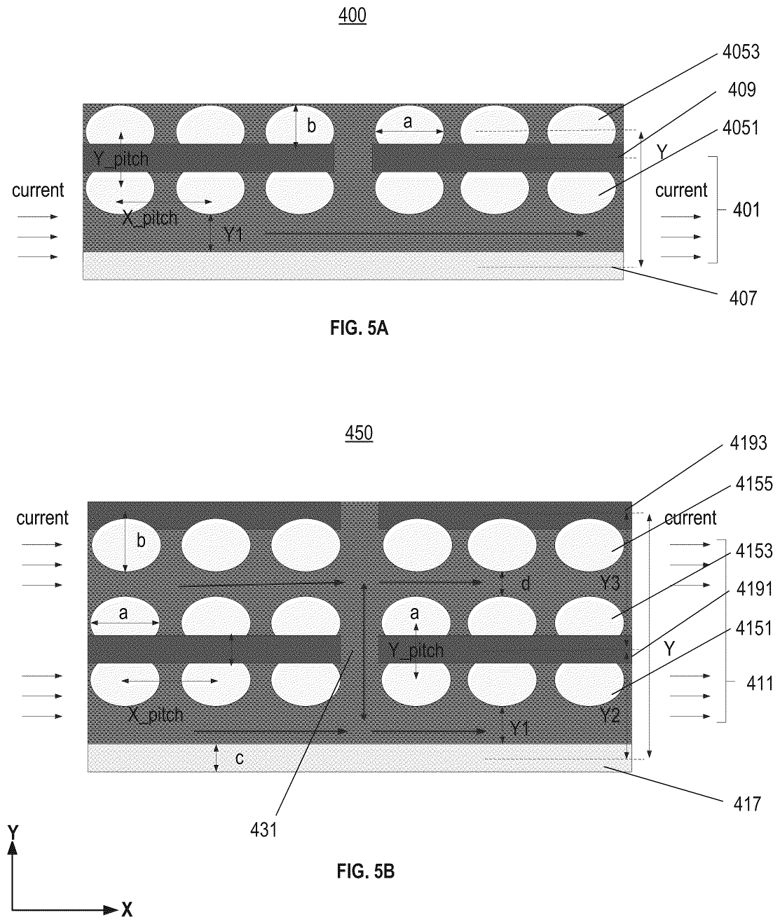

Also, FIG. 5A shows an enlarged view of part of the staircase region of the memory cell array of 3D memory device 400 according to some implementations of the present disclosure. As shown in FIG. 5A, the current path, in the present implementation, may only have single current path with a width of Y1, which is ranged from isolation structure 407 to a first dummy channel structure 4051 which is adjacent to first slit structure 409 and at a close side of first slit structure 409 toward isolation structure 407.

In some implementations, the width of bridge structure 401 may be no more than 1.25 μm, e.g., 0.50 μm, 0.55 μm, 0.60 μm, 0.65 μm, 0.70 μm, 0.75 μm, 0.80 μm, 0.85 μm, 0.90 μm, 0.95 μm, 1.00 μm, 1.05 μm, 1.10 μm, 1.15 μm, 1.20 μm, 1.25 μm, etc.

In some implementations, the diameter of first dummy channel structure 4051 and/or second dummy channel structure 4053 may be ranged from 0.05 μm to 0.50 μm, e.g., 0.05 μm, 0.10 μm, 0.15 μm, 0.20 μm, 0.25 μm, 0.30 μm, 0.35 μm, 0.40 μm, 0.45 μm, 0.50 μm, etc.

In some implementations, the distance between two centers of adjacent dummy channel structures (e.g., first dummy channel structure 4051 and/or second dummy channel structure 4053) may be ranged from 0.05 μm to 1.00 μm, e.g., 0.05 μm, 0.10 μm, 0.15 μm, 0.20 μm, 0.25 μm, 0.30 μm, 0.35 μm, 0.40 μm, 0.45 μm, 0.50 μm, 0.55 μm, 0.60 μm, 0.65 μm, 0.7 μm, 0.75 μm, 0.80 μm, 0.85 μm, 0.90 μm, 0.95 μm, 0.10 μm, etc.

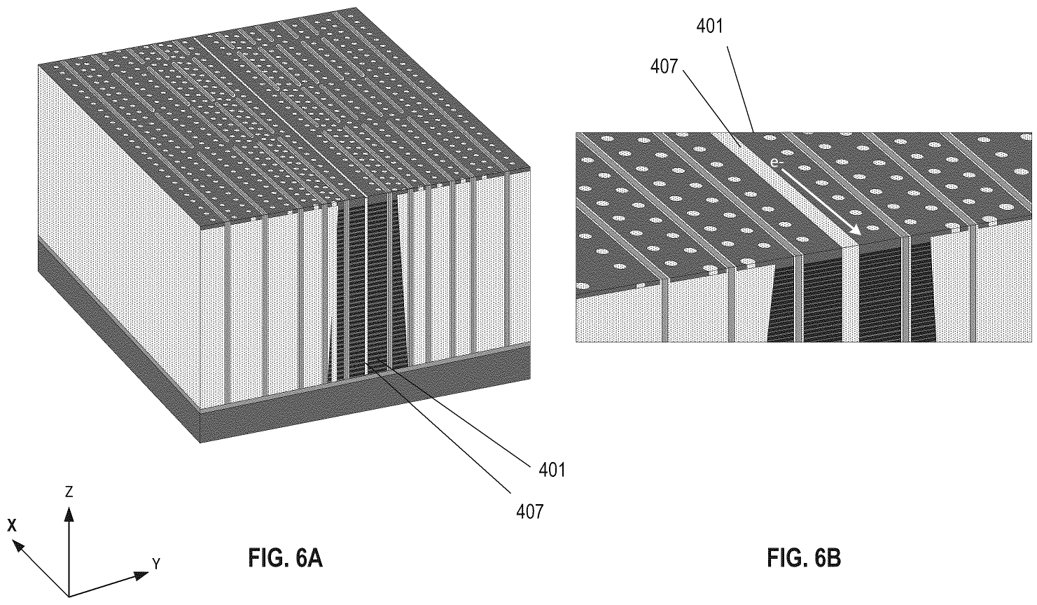

FIGS. 6A-6B show perspective views of part of the staircase region of the memory cell array of 3D memory device 400 according to some implementations of the present disclosure. As shown in FIG. 6A, bridge structures 401 extend in the z-direction and the x-direction, and isolation structure 407 extends in the z-direction and separates two adjacent bridge structures 401 and defines the boundary of two adjacent memory blocks. Also, as shown in FIG. 6B, an enlarged view of FIG. 6A, there is only a single current path defined by isolation structure 407 and the dummy channel structures.

To address the issue mentioned above, FIG. 4B shows an enlarged view of part of the staircase region of the memory cell array of another 3D memory device 450 according to some implementations of the present disclosure. For the simplicity of description, parts of 3D memory device 450 labeled with the same numerals are the same as or similar to those in 3D memory device 300, and the detailed descriptions are not repeated herein.

As shown in FIG. 4B, bridge structure 411 and isolation structure 417 are arranged along the x-direction in the staircase region. The width (e.g., the distance along the y-direction) of bridge structure 411 may be ranged from isolation structure 417 to a second slit structure 4193 or to a fourth dummy channel structure (not shown), which is adjacent to second slit structure 4193 and at a remote side of second slit structure 4193 toward isolation structure 417.

Also, FIG. 5B shows an enlarged view of part of the staircase region of the memory cell array of 3D memory device 450 according to some implementations of the present disclosure. As shown in FIG. 5B, the current path, in the present implementation, may have at least two current paths with a width of Y1 plus d, where the Y1 is ranged from isolation structure 417 to a first dummy channel structure 4151, which is adjacent to a first slit structure 4191 and at a close side of first slit structure 4191 toward isolation structure 417, and the d is ranged from a second dummy channel structure 4153, which is adjacent to first slit structure 4191 and at a remote side of first slit structure 4191 toward isolation structure 417, to a third dummy channel structure 4155, which is adjacent to second slit structure 4193 and at a close side of second slit structure 4193 toward isolation structure 417. As such, having at least two current paths, may increase the reliability of the memory device. Furthermore, since both first and second slit structures 4191 and 4193 discontinuously extend in the y-direction, two current paths of bridge structure 411 may be interconnected through portions 431 between the discontinuous slit structures. It is noted that, although it can be more than two current paths than that in the present implementation, the wider the bridge structure is, the more area consumption the bridge structure creates, thereby reducing the overall efficiency and performance of the memory device. In some implementations, the width of bridge structure 411 may not be more than a width of a memory finger.

In some implementations, the width of bridge structure 411 may be no less than 1.25 μm, e.g., 1.25 μm, 1.26 μm, 1.27 μm, 1.28 μm, 1.29 μm, 1.30 μm, 1.35 μm, 1.40 μm, 1.45 μm, 1.50 μm, 1.55 μm, 1.60 μm, 1.65 μm, 1.70 μm, 1.75 μm, 1.80 μm, 1.85 μm, 1.90 μm, 1.95 μm, 2.00 μm, 2.50 μm, 3.00 μm, etc. In some implementations where there are more than two current paths, the width of bridge structure 411 may be more than 3.00 μm.

In some implementations, the diameter of first dummy channel structure 4151, second dummy channel structure 4153, and/or third dummy channel structure 4155 may be ranged from 0.05 μm to 0.50 μm, e.g., 0.05 μm, 0.10 μm, 0.15 μm, 0.20 μm, 0.25 μm, 0.30 μm, 0.35 μm, 0.40 μm, 0.45 μm, 0.50 μm, etc.

In some implementations, the distance between two centers of adjacent dummy channel structures (e.g., first dummy channel structure 4151, second dummy channel structure 4153, and/or third dummy channel structure 4155) may be ranged from 0.05 μm to 1.00 μm, e.g., 0.05 μm, 0.10 μm, 0.15 μm, 0.20 μm, 0.25 μm, 0.30 μm, 0.35 μm, 0.40 μm, 0.45 μm, 0.50 μm, 0.55 μm, 0.60 μm, 0.65 μm, 0.7 μm, 0.75 μm, 0.80 μm, 0.85 μm, 0.90 μm, 0.95 μm, 0.10 μm, etc.

FIGS. 6C-6D show perspective views of part of the staircase region of the memory cell array of 3D memory device 450 according to some implementations of the present disclosure. As shown in FIG. 6C, bridge structures 411 extend in the z-direction and the x-direction, and isolation structure 417 extends in the z-direction separating two adjacent bridge structures 411 and defining the boundary of two adjacent memory blocks. Also, as shown in FIG. 6D, an enlarged view of FIG. 6C, there are two current paths defined by isolation structure 417, the dummy channel structures, and the slit structures.

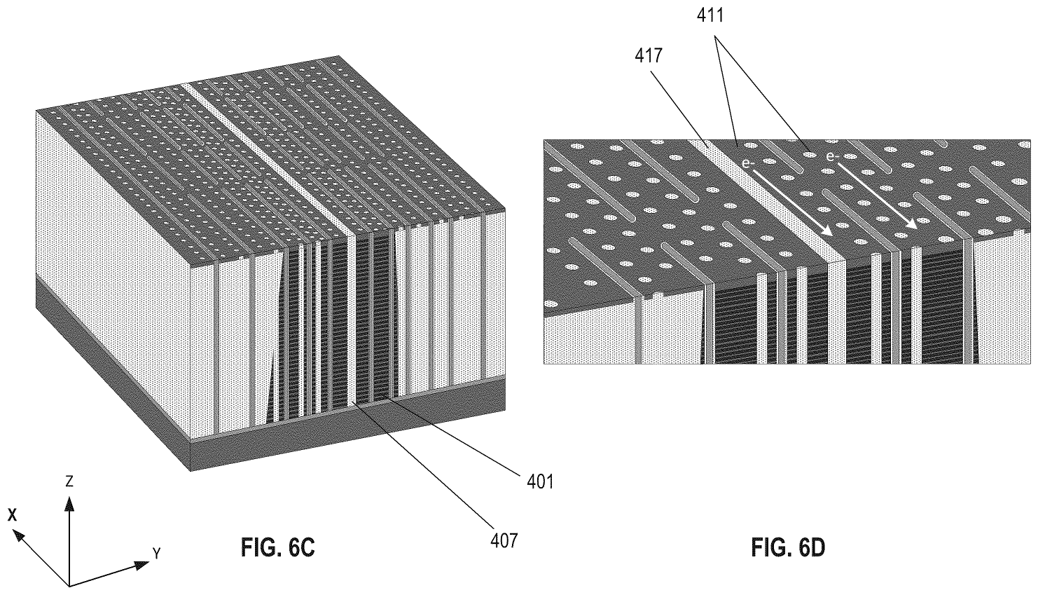

FIG. 7 illustrates a block diagram of a system 700 having a memory device, according to some aspects of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more memory devices 704 and a memory controller 706. Host 708 can be a processor of an electronic device, such as a central processing unit (CPU), or a system-on-chip (SoC), such as an application processor (AP). Host 708 can be configured to send or receive the data to or from memory devices 704.

Memory devices 704 can be any memory devices disclosed herein, such as 3D memory devices 100, 300, 400, or 450. In some implementations, each 3D memory device 704 includes a 3D memory device, as described above in detail.

Memory controller 706 is coupled to memory device 704 and host 708 and is configured to control memory device 704, according to some implementations. Memory controller 706 can manage the data stored in memory device 704 and communicate with host 708. In some implementations, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program operations. Memory controller 706 can also be configured to manage various functions with respect to the data stored or to be stored in memory device 704 including, but not limited to bad-block management, garbage collection, logical-to-physical address conversion, wear leveling, etc. In some implementations, memory controller 706 is further configured to process error correction codes (ECCs) with respect to the data read from or written to memory device 704. Any other suitable functions may be performed by memory controller 706 as well, for example, formatting memory device 704. Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

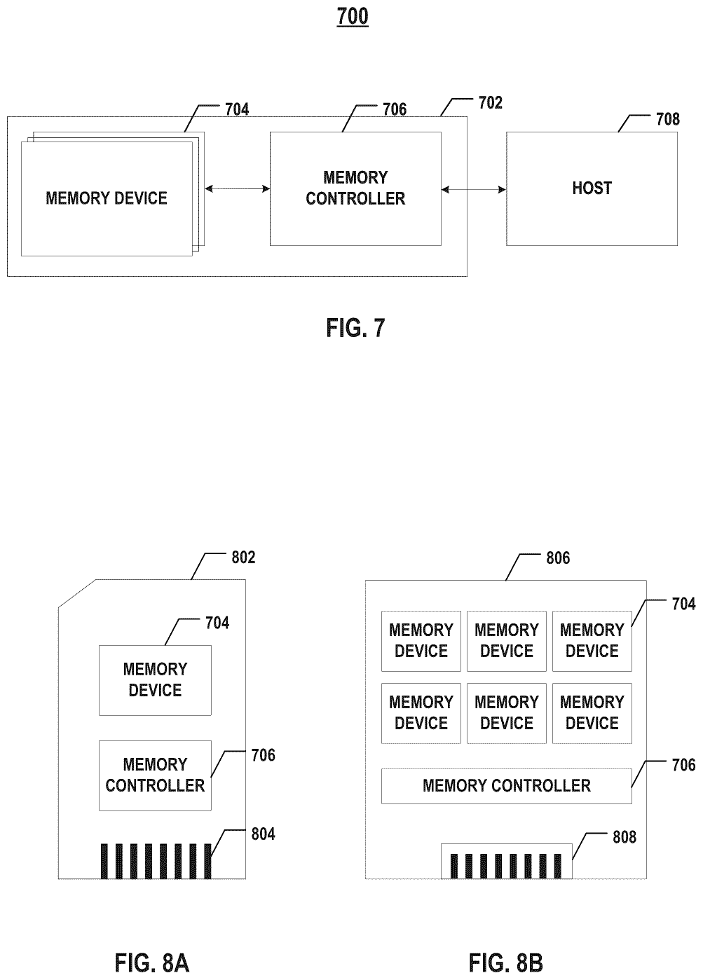

Memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a single memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 802 can further include a memory card connector 804 coupling memory card 802 with a host (e.g., host 708 in FIG. 7). In another example as shown in FIG. 8B, memory controller 706 and multiple memory devices 704 may be integrated into an SSD 806. SSD 806 can further include an SSD connector 808 coupling SSD 806 with a host (e.g., host 708 in FIG. 7). In some implementations, the storage capacity and/or the operation speed of SSD 806 is greater than those of memory card 802.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a stack structure comprising alternating conductive layers and dielectric layers and having at least two core regions and a staircase region between the two core regions; and
bridge structures connecting the two core regions and extending through the staircase region in a first direction, wherein a first bridge structure of the bridge structures comprises at least two current paths between the two core regions.

2. The 3D memory device of claim 1, further comprising:
an isolation structure extending through the staircase region in the first direction;
a first slit structure discontinuously extending through the staircase region in the first direction; and
a second slit structure discontinuously extending through the staircase region in the first direction, wherein a first current path of the at least two current paths is between the isolation structure and the first slit structure, and a second current path of the at least two current paths is between the first slit structure and the second slit structure.

3. The 3D memory device of claim 2, wherein the isolation structure separates two bridge structures in two respective memory blocks.

4. The 3D memory device of claim 2, wherein the first current path and the second current path are interconnected through discontinuous portions of the first slit structure.

5. The 3D memory device of claim 2, further comprising:
first dummy channel structures extending into the stack structure and being arranged side-by-side in the first direction and in contact with the first slit structure at a close side toward the isolation structure;
second dummy channel structures extending into the stack structure and being arranged side-by-side in the first direction and in contact with the first slit structure at a remote side toward the isolation structure; and
third dummy channel structures extending into the stack structure and being arranged side-by-side in the first direction and in contact with the second slit structure at a close side toward the isolation structure, wherein the first current path of the at least two current paths is between the isolation structure and the first dummy channel structures, and the second current path of the at least two current paths is between the second dummy channel structures and the third dummy channel structures.

6. The 3D memory device of claim 5, wherein a width of the first bridge structure in a remote side toward a substrate is ranged from the isolation structure to that of the third dummy channel structures, and the width of the first bridge structure is no less than 1.25 μm.

7. The 3D memory device of claim 1, further comprising: channel structures each extending in the stack structure in the core regions.

8. The 3D memory device of claim 1, wherein the first bridge structure connects two of the conductive layers in two respective core regions.

9. The 3D memory device of claim 1, wherein a material of the bridge structures comprises tungsten (W), cobalt (Co), copper (Cu), aluminum (Al), polycrystalline silicon (polysilicon), doped silicon, silicides, or any combination thereof.

10. A three-dimensional (3D) memory device, comprising:
a stack structure comprising alternating conductive layers and dielectric layers and having at least two core regions and a staircase region between the two core regions;
bridge structures connecting the two core regions and extending through the staircase region in a first direction;
an isolation structure extending through the staircase region in the first direction;
a first slit structure discontinuously extending through the staircase region in the first direction;
a second slit structure discontinuously extending through the staircase region in the first direction; and
at least three dummy channel structures extending into the stack structure and being arranged side-by-side in the first direction and in contact with the first slit structure or the second slit structure.

11. The 3D memory device of claim 10, wherein the at least three dummy channel structures comprise:
first dummy channel structures extending into the stack structure and being arranged side-by-side in the first direction and in contact with the first slit structure at a close side toward the isolation structure;
second dummy channel structures extending into the stack structure and being arranged side-by-side in the first direction and in contact with the first slit structure at a remote side toward the isolation structure; and
third dummy channel structures extending into the stack structure and being arranged side-by-side in the first direction and in contact with the second slit structure at a close side toward the isolation structure.

12. The 3D memory device of claim 11, wherein the isolation structure separates two bridge structures in two respective memory blocks.

13. The 3D memory device of claim 11, wherein a width of one of the bridge structures in a remote side toward a substrate is ranged from the isolation structure to that of the third dummy channel structures, and the width of the one of the bridge structures is no less than 1.25 μm.

14. The 3D memory device of claim 11, further comprising channel structures each extending in the stack structure in the core regions.

15. The 3D memory device of claim 11, wherein one of the bridge structures connects two of the conductive layers in two respective core regions.

16. The 3D memory device of claim 11, wherein a material of the bridge structures comprises tungsten (W), cobalt (Co), copper (Cu), aluminum (Al), polycrystalline silicon (polysilicon), doped silicon, silicides, or any combination thereof.

17. A system, comprising:
a three-dimensional (3D) memory device configured to store data, the 3D memory device comprising:
a stack structure comprising alternating conductive layers and dielectric layers and having at least two core regions and a staircase region between the two core regions; and
bridge structures connecting the two core regions and extending through the staircase region in a first direction, wherein a first bridge structure of the bridge structures comprises at least two current paths between the two core regions; and
a memory controller coupled to the 3D memory device and configured to control the 3D memory device.

18. The system of claim 17, wherein the 3D memory device further comprises:
an isolation structure extending through the staircase region in the first direction;
a first slit structure discontinuously extending through the staircase region in the first direction; and
a second slit structure discontinuously extending through the staircase region in the first direction, wherein a first current path of the at least two current paths is between the isolation structure and the first slit structure, and a second current path of the at least two current paths is between the first slit structure and the second slit structure.

19. The system of claim 18, wherein the first current path and the second current path are interconnected through discontinuous portions of the first slit structure.

20. The system of claim 18, wherein the 3D memory device further comprises:
first dummy channel structures extending into the stack structure and being arranged side-by-side in the first direction and in contact with the first slit structure at a close side toward the isolation structure;
second dummy channel structures extending into the stack structure and being arranged side-by-side in the first direction and in contact with the first slit structure at a remote side toward the isolation structure; and
third dummy channel structures extending into the stack structure and being arranged side-by-side in the first direction and in contact with the second slit structure at a close side toward the isolation structure, wherein the first current path of the at least two current paths is between the isolation structure and the first dummy channel structures, and the second current path of the at least two current paths is between the second dummy channel structures and the third dummy channel structures.
